(19) United States
(12) Patent Application Publication
(10) Pub. No.: US 2008/0241429 A1
(43) Pub. Date: Oct. 2, 2008

(54) COLOR FILTER AND LIQUID CRYSTAL DISLAY PANEL USING THE SAME

(75) Inventors: Wen-Lung Chen, Hsinchu (TW); Shu-Chin Lee, Hsinchu (TW); Fu-Chuan Tsai, Hsinchu (TW); Wei-Ya Wang, Hsinchu (TW); Yong-Mao Lin, Hsinchu (TW); Chun-Chieh Tsao, Hsinchu (TW); Yung-Lung Lin, Hsinchu (TW); Yen-Heng Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 11/775,877

(22) Filed: Jul. 11, 2007

(30) Foreign Application Priority Data
Mar. 30, 2007 (TW) 96111249

(51) Int. Cl. C09K 19/02; G03F 1/00

(52) U.S. Cl. 428/1.3; 430/7

(57) ABSTRACT

A color filter including a substrate, a bank and a plurality of color filter films is provided. The bank is disposed on the substrate and has many openings. The bank has both a bottom surface contacting the substrate and a top surface exceeding the bottom surface. An outline of the bottom surface does not exceed that of the top surface. Besides, the color filter films are disposed on the substrate exposed by the openings, respectively, and each of the color filter films has a curved top surface. In the above-mentioned color filter, wetability between the bank and the color filter films is favorable.

### CROSS-REFERENCE TO RELATED APPLICATION

This application claims the priority benefit of Taiwan application serial no. 96111249, filed Mar. 30, 2007. All disclosure of the Taiwan application is incorporated herein by reference.

### BACKGROUND OF THE INVENTION

1. Field of the Invention

The present invention generally relates to a color filter and a liquid crystal display (LCD) panel using the same. More particularly, the present invention relates to a color filter with great color saturation and the LCD panel using the same.

2. Description of Related Art

Recently, a method for forming a color filter by implementing an inkjet printing process has been developed. The method includes first forming a black matrix on a substrate. The black matrix has a plurality of openings. Next, the inkjet printing process is performed to inject color inks (red, green and blue) into openings of the black matrix. Thereafter, a thermal baking process is carried out to solidify the color inks, so as to form the color filter.

FIG. 1 is a schematic view depicting a formation of a hydrophobic film on a conventional black matrix with use of fluorine-containing plasma. Referring to FIG. 1, a conventional color filter 100 includes a substrate 110 and a black matrix 112 disposed thereon. The black matrix 112 has a plurality of openings P (only one opening is depicted in FIG. 1). To prevent an overflow or an intermixture of color inks, a hydrophobic process 120 is usually performed on a surface of the black matrix 112 to form a fluorine-containing hydrophobic film 130. As shown in FIG. 1, the fluorine-containing plasma may simultaneously react with a top surface 114 of the black matrix 112 and a side surface 116 thereof, such that the fluorine-containing hydrophobic film 130 is formed on the top surface 114 of the black matrix 112 and the side surface 116 thereof.

### SUMMARY OF THE INVENTION

The present invention is directed to a color filter for improving wetability between a bank and color filter films.

The present invention is further directed to an LCD panel on which the displayed image has great color saturation.

The present invention provides a color filter including a substrate, a bank and a plurality of color filter films. The bank is disposed on the substrate and has a plurality of openings. Besides, the bank has a bottom surface contacting the substrate and a top surface larger than the bottom surface, and an outline of the bottom surface does not exceed that of the top surface. Moreover, each of the color filter films is disposed on the substrate exposed by one of the openings, respectively, and each of the color filter films has a curved top surface.

According to an embodiment of the present invention, the top surface of the bank is hydrophobic.

According to an embodiment of the present invention, the width of the bank is increased from the bottom surface of the bank to the top surface thereof at a constant/or uniform ratio or at a different ratio.

According to an embodiment of the present invention, the width of the bank from the bottom surface to the top surface is firstly decreased and then increased.

According to an embodiment of the present invention, the width of the bank from the bottom surface to the top surface firstly remains the same and is then increased.

According to an embodiment of the present invention, the width of the bank from the bottom surface to the top surface firstly remains the same, and the width is then increased and finally decreased.

According to an embodiment of the present invention, the curved top surface is protruding in the middle and concave at the peripheries.

According to an embodiment of the present invention, the curved top surface is concave in the middle and protruding at the peripheries.

According to an embodiment of the present invention, the color filter films include red filter films, green filter films and blue filter films.

According to an embodiment of the present invention, the bank includes a plurality of side surfaces substantially contacting the color filter films, and the side surfaces of the bank are hydrophilic.

According to an embodiment of the present invention, the bank includes a photoresist, a black matrix, a metal, a dry film or combinations thereof.

According to an embodiment of the present invention, a height of the bank is approximately 1-5 micrometers.

According to an embodiment of the present invention, a width of each of the openings is approximately 50-300 micrometers, and a length of each of the openings is approximately 100-500 micrometers.

According to an embodiment of the present invention, a length of each of the openings is approximately 100-500 micrometers or 350-450 micrometers.

According to an embodiment of the present invention, an outline of the top surface substantially covers that of the bottom surface.

The present invention further provides an LCD panel including an array substrate, the color filter as described in any of the above embodiments, and a liquid crystal layer. The liquid crystal layer is sandwiched between the array substrate and the color filter.

According to an embodiment of the present invention, the array substrate includes a thin film transistor (TFT) array substrate.

In the present invention, the opening of the bank having a wider top surface and a narrower bottom surface is filled with color inks completely and uniformly during the fabrication of the color filter. Thus, the color filter of the present invention is capable of improving the color saturation.

In order to make the above and other objects, features and advantages of the present invention more comprehensible, several embodiments accompanied with figures are described in detail below.

### BRIEF DESCRIPTION OF THE DRAWINGS

FIG. 1 is a schematic view depicting a formation of a hydrophobic film on an island-structured black matrix with use of fluorine-containing plasma.

FIGS. 2, 3, 4A and 4B are partial cross-sectional schematic views of a color filter according to four embodiments of the present invention, respectively.

FIG. 5 is a flowchart illustrating an inkjet printing process performed on the conventional color filter and on a color filter of the present invention.

FIG. 6 is a top schematic view illustrating a color filter 200 (or 300, 400A, 400B) of the present invention.

FIG. 7 is a schematic view of an LCD panel according to an embodiment of the present invention.

### DESCRIPTION OF EMBODIMENTS

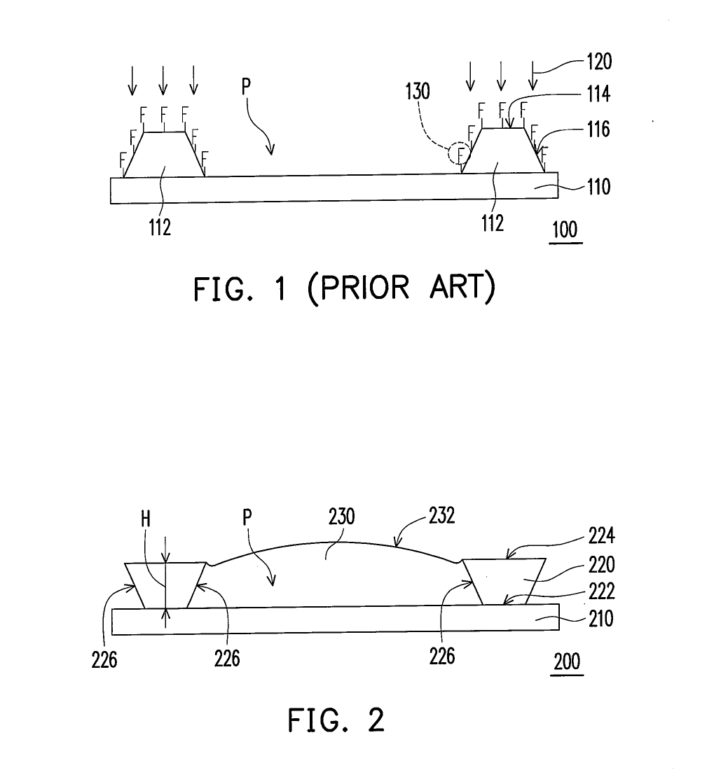

In FIG. 1, when the openings P are filled with the color inks, the color inks are not able to be adhered to the side surface 116 of the black matrix 112 due to the hydrophobic properties of said side surface 116, such that the color inks are not apt to be uniformly filled into the openings P. Thereby, unfavorable wetability between the color filter films and the black matrix may result in undesired color saturation of the color filter. It is known from the description of the related art that the hydrophobic process is usually performed on a surface of the black matrix to prevent an overflow or an intermixture of the color inks during the implementation of the inkjet printing process for fabricating the color filters. However, after the hydrophobic process is carried out, the openings of the conventional island-structured black matrix cannot be completely filled with the color inks in most cases due to the wetability of the side surface of the black matrix. Accordingly, the present invention brings forth several designs of the color filters to resolve said issue.

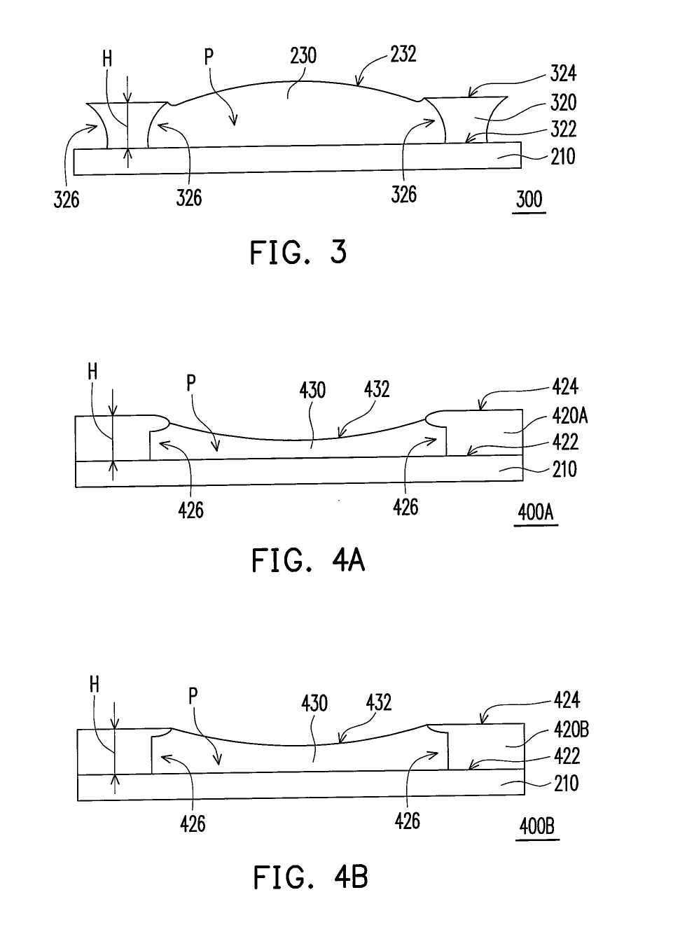

FIGS. 2, 3, 4A and 4B are partial cross-sectional schematic views of a color filter according to four embodiments of the present invention, respectively. Referring to FIG. 2 first, a color filter 200 includes a substrate 210, a bank and a plurality of color filter films 230. The bank may be a photoresist, a black matrix, a metal, a dry film or combinations thereof, for example, and a black matrix 220 is taken for an example in the present embodiment. The black matrix 220 is disposed on the substrate 210 and has a plurality of openings P. The black matrix 220 has both a bottom surface 222 contacting the substrate 210 and a top surface 224 exceeding the bottom surface 222. Besides, an outline of the bottom surface 222 does not exceed that of the top surface 224. Moreover, each of the color filter films 230 is disposed on the substrate 210 exposed by one of the openings P, respectively, and each of the color filter films 230 has a curved top surface 232.

To prevent a sputter or an overflow of the color inks during the inkjet printing process, a hydrophobic process may be performed on the black matrix 220 with use of carbon tetrafluoride (CF₄)-containing plasma or sulfur hexafluoride (SF₆)-containing plasma in the present embodiment, such that a surface of the black matrix 220 may be characterized by the hydrophobic properties. In the color filter 200 of the present invention, the top surface 224 of the black matrix 220 is larger than the bottom surface 222 thereof, and the outline of the bottom surface 222 does not exceed that of the top surface 224. Thus, during the implementation of the hydrophobic process on the top surface 224 of the black matrix 220 with use of fluorine-containing plasma, the top surface 224 of the black matrix 220 is equipped with the hydrophobic properties since the fluorine-containing plasma merely reacts with the top surface 224 of the black matrix 220. In other words, other surfaces of the black matrix 220 may not be featured by the hydrophobic properties except for the top surface 224. Namely, the black matrix 220 has a plurality of side surfaces 226 adhered to or contacting the color filter films, and the side surfaces 226 are hydrophilic. In the inkjet printing process, the color inks are, for example, pigments, dyes or a combination thereof.

In particular, a width of the black matrix 220 from the bottom surface 222 to the top surface 224 is, for example, increased at a constant or uniform ratio according to the present embodiment, such that a cross-section of the black matrix 220 illustrates that the black matrix 220 appears to be a trapezoid (as illustrated in FIG. 2). In FIG. 3, a width of a black matrix 320 from a bottom surface 322 to a top surface 324 is, for example, increased at a different ratio, such that a cross-section of the black matrix 320 shows that the black matrix 220 appears to have curved edges. Moreover, with reference to FIG. 4A, a width of a black matrix 420A of a color filter 400A from a bottom surface 422 to a top surface 424 may remain the same, and the width is then increased and finally decreased, for example. As such, the height of the black matrix 420A is substantially greater than that of the thickness of color filter films 430. Besides, as shown in FIG. 4B, it is of certainty that a width of a black matrix 420B from the bottom surface 422 to the top surface 424 may also remain the same and then be increased, for example. In details, the black matrixes 220, 320, 420A and 420B are integrally formed or have a multi-layered structure, for example. Meanwhile, a height H of the black matrixes 220, 320, 420A and 420B is approximately 1-5 micrometers, preferably 2 micrometers, for example.

It should be noted that an amount of the color inks filled into the openings P during the inkjet printing process may be adjusted when the color filters 200, 300, 400A and 400B are actually fabricated. Thereby, color filter films 230 or 430 may have different types of appearances. Specifically, the curved top surface 232 of the color filter film 230 is protruding in the middle and concave at the peripheries in the color filters 200 and 300. By contrast, a curved top surface 432 of the color filter film 430 is concave in the middle and protruding at the peripheries in the color filters 400A and 400B.

According to a preferred embodiment of the present invention, the color filter films 230 and 430 of the color filters 200, 300, 400A and 400B are, for example, red filter films, green filter films and blue filter films. However, in other embodiments, the color filter film 230 or 430 may have different combinations of colors.

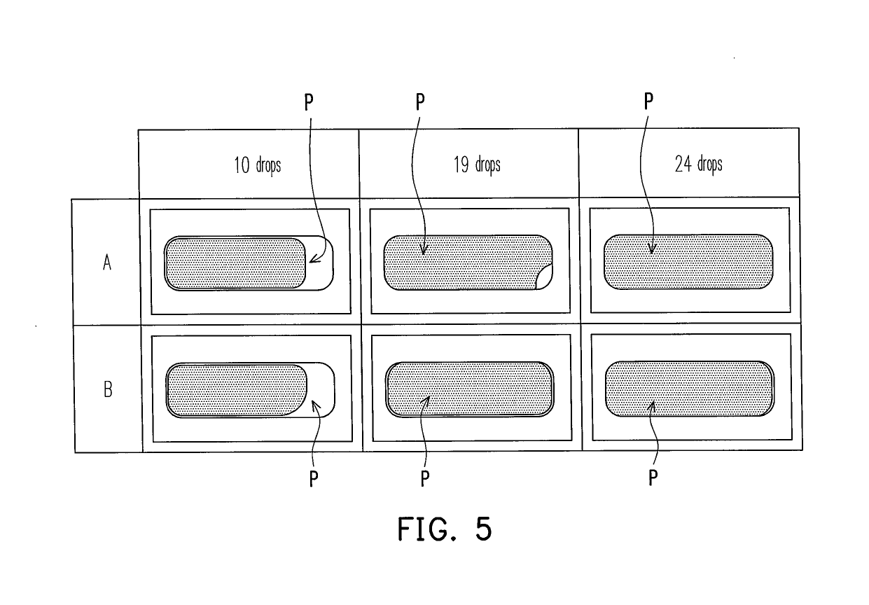

To further elaborate the advantages of the color filters 200, 300, 400A and 400B disclosed in the present invention, FIG. 5, a flowchart illustrating the inkjet printing process performed on the conventional color filter and on the color filter of the present invention, is then provided. Referring to FIG. 5, row A and row B respectively represent the process of gradually dropping the color inks in the conventional color filter 100 and in the color filter 200 (or 300, 400A, 400B) of the present invention during the implementation of the inkjet printing process. Comparatively speaking, the distribution of the color inks in the color filter 200 and in the color filter 100 is similar when 10 drops of the color inks are dropped. As 19 drops of the color inks are dropped, the opening P of the color filter 200 is roughly filled, while the peripheral area of the opening P of the color filter 100 still remains without ink dropped due to the hydrophobic properties of the side surface of the black matrix. As 24 drops of the color inks are dropped, the opening P of the color filter 200 is completely filled, while the edge area of the opening P on the color filter 100 is still left undropped.

Based on the above, the color inks are apt to be uniformly and completely filled into the opening P of the color filter 200 (or 300, 400A, 400B), and thus the color filter 200 (or 300, 400A, 400B) may have better color saturation, while the same effect cannot be achieved by the color filter 100.

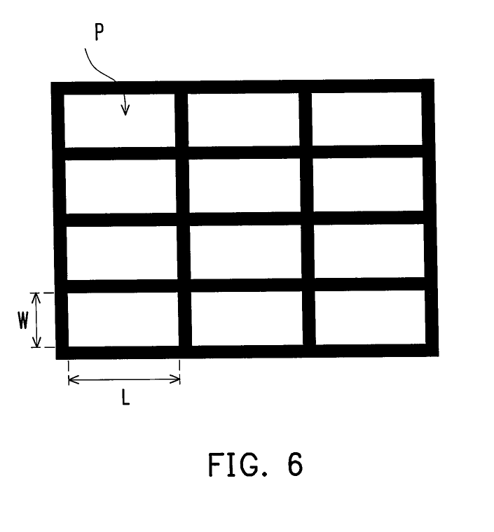

FIG. 6 is a top schematic view illustrating the color filter 200 (or 300, 400A, 400B) of the present invention. Referring to FIG. 6, in the color filter 200 (or 300, 400A, 400B), a width W of the opening P of the black matrix 220 (or 320, 420A, 420B) is approximately 50-300 micrometers, preferably 100-200 micrometers, for example. Besides, a length L of said opening P is approximately 100-500 micrometers, preferably 350-450 micrometers, for example.

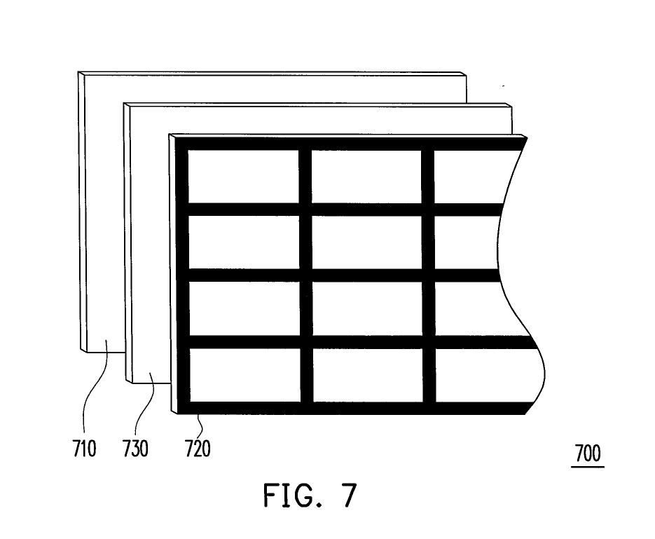

On the other hand, FIG. 7 is a schematic view of an LCD panel according to an embodiment of the present invention. With reference to FIG. 7, an LCD panel 700 includes an array substrate 710, a color filter 720, and a liquid crystal layer 730. The color filter 720 is arranged opposite to the array substrate 710, and the liquid crystal layer 730 is sandwiched between the array substrate 710 and the color filter 720. It should be noted that the color filter 720 is, for example, any of the color filters 200, 300, 400A and 400B discussed in the above embodiments. Therefore, the images displayed on the LCD panel 700 may have preferable color saturation.

In view of the foregoing, the black matrix having a wider top surface and a narrower bottom surface is adopted in the present invention. As a result, after the hydrophobic process is implemented, only the top surface of the black matrix is characterized by the hydrophobic properties. Thus, the color inks are capable of uniformly filling the openings of the black matrix when the color filter films are formed by filling the color inks into said openings. That is to say, the color filter of the present invention has the advantage of desired color saturation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A color filter, comprising:
a substrate;
a bank disposed on the substrate, wherein the bank has a plurality of openings, a bottom surface, and a top surface larger than the bottom surface; and
a plurality of color filter films, wherein each of the color filter films is respectively disposed within one of the openings, and the at least one color filter film has a curved top surface.

2. The color filter as claimed in claim 1, wherein a top surface of the bank is hydrophobic.

3. The color filter as claimed in claim 1, wherein a width of the bank is increased from a bottom surface of the bank to a top surface thereof at a constant ratio.

4. The color filter as claimed in claim 1, wherein a width of the bank is increased from a bottom surface of the bank to a top surface thereof at a variable ratio.

5. The color filter as claimed in claim 1, wherein a width of the bank from a bottom surface of the bank to a top surface thereof is firstly decreased and then increased.

6. The color filter as claimed in claim 1, wherein a width of the bank from a bottom surface of the bank to a top surface thereof firstly remains the same and is then increased.

7. The color filter as claimed in claim 1, wherein a width of the bank from a bottom surface of the bank to the top surface thereof firstly remains the same, and the width is then increased and finally decreased.

8. The color filter as claimed in claim 1, wherein the curved top surface is protruding in the middle and concave at the peripheries.

9. The color filter as claimed in claim 1, wherein the curved top surface is concave in the middle and protruding at the peripheries.

10. The color filter as claimed in claim 1, wherein the color filter films includes at least one red filter film, at least one green filter film and at least one blue filter film.

11. The color filter as claimed in claim 1, wherein the bank includes a plurality of side surfaces adhered to the color filter films, and the side surfaces of the bank are hydrophilic surfaces.

12. The color filter as claimed in claim 1, wherein the bank includes a photoresist, a black matrix, a metal, a dry film or combinations thereof.

13. The color filter as claimed in claim 1, wherein a height of the bank is approximately 1-5 micrometers.

14. The color filter as claimed in claim 1, wherein a width of each of the openings is approximately 50-300 micrometers.

15. The color filter as claimed in claim 14, wherein a length of each of the openings is approximately 100-500 micrometers.

16. The color filter as claimed in claim 1, wherein a length of each of the openings is approximately 100-500 micrometers.

17. The color filter as claimed in claim 1, wherein a length of each of the openings is approximately 350-450 micrometers.

18. The color filter as claimed in claim 1, wherein an outline of the top surface substantially covers that of the bottom surface.

19. An LCD panel, comprising:
an array substrate;
the color filter as claimed in claim 1; and
a liquid crystal layer sandwiched between the array substrate and the color filter.

20. The LCD panel as claimed in claim 19, wherein the array substrate comprises a thin film transistor (TFT) array substrate.
